(19) United States
(12) Patent Application Publication
(10) Pub. No.: US 2022/0069176 A1
(43) Pub. Date: Mar. 3, 2022

(54) WAVELENGTH CONVERSION ELEMENT, LIGHT SOURCE APPARATUS, IMAGE PROJECTION APPARATUS, AND MANUFACTURING METHOD OF THE WAVELENGTH CONVERSION ELEMENT

(71) Applicant: CANON KABUSHIKI KAISHA, Tokyo (JP)

(72) Inventors: Yuya Kurata, Tochigi (JP); Hiroshi Yamamoto, Saitama (JP); Shigefumi Watanabe, Tochigi (JP)

(21) Appl. No.: 17/408,601

(22) Filed: Aug. 23, 2021

(30) Foreign Application Priority Data
Sep. 1, 2020 (JP) 2020-146629
Mar. 12, 2021 (JP) 2021-040060

(51) Int. Cl. H01L 33/50; H01L 33/60; H01L 25/075; G03B 21/20

(52) U.S. Cl. CPC H01L 33/505; H01L 33/502; G03B 21/204; H01L 25/0753; H01L 33/60

(57) ABSTRACT

A wavelength conversion element includes a wavelength conversion layer configured to convert light having a first wavelength into light having a second wavelength, and a flattening layer formed on at least one surface of the wavelength conversion layer. The flattening layer has a surface roughness smaller than that of the wavelength conversion layer. The wavelength conversion layer is made of a sintered body obtained by sintering a phosphor material and a ceramic material.

### BACKGROUND OF THE INVENTION

### Field of the Invention

The present invention relates to a wavelength conversion element, a light source apparatus, an image projection apparatus, and a manufacturing method of the wavelength conversion element.

### Description of the Related Art

Japanese Patent Laid-Open No. (“JP”) 2009-277516 discloses a blue laser diode (LD) that emits blue light and a wavelength conversion element that converts part of a wavelength of the light from the blue LD. The wavelength conversion element disclosed in JP 2009-277516 has a structure in which a phosphor (fluorescent) material is contained in a binder made of an organic material, and the binder is coated on a dichroic layer to serve as a reflective layer for reflecting fluorescent light. JP 2019-66880 discloses a wavelength conversion element having a structure in which a phosphor made of a ceramic material is sintered, a reflective layer is formed on its surface, and light from a blue LD enters it.

The wavelength conversion element disclosed in JP 2009-277516 needs to rotate a phosphor wheel in order to suppress a reliability deterioration of the binder made of the organic material due to the heat in converting the light from the blue LD into the fluorescent light. The wavelength conversion element disclosed in JP 2019-66880 is a sintered phosphor, and contains voids due to sintering. Thus, when the reflective layer is evaporated on the surface of the sintered phosphor, the reflective layer is not formed above the voids, and the light utilization efficiency may deteriorate.

### SUMMARY OF THE INVENTION

The present invention provides a wavelength conversion element, a light source apparatus, an image projection apparatus, and a manufacturing method for a wavelength conversion element, each of which can improve reliability and light utilization efficiency.

A wavelength conversion element according to one aspect of the present invention includes a wavelength conversion layer configured to convert light having a first wavelength into light having a second wavelength, and a flattening layer formed on at least one surface of the wavelength conversion layer. The flattening layer has a surface roughness smaller than that of the wavelength conversion layer. A light source apparatus and an image projection apparatus each having the above wavelength conversion element also constitute another aspect of the present invention. The wavelength conversion layer is made of a sintered body obtained by sintering a phosphor material and a ceramic material.

A manufacturing method of a wavelength conversion element according to another aspect of the present invention includes the steps of forming a wavelength conversion layer configured to convert light having a first wavelength into light having a second wavelength, and forming a flattening layer on at least one surface of the wavelength conversion layer. The wavelength conversion layer is made of a sintered body obtained by sintering a phosphor material and a ceramic material.

A manufacturing method of a wavelength conversion element according to another aspect of the present invention includes the steps of forming a wavelength conversion layer configured to convert light having a first wavelength into light having a second wavelength, and bonding at least one surface of the wavelength conversion layer and a reflective layer held on a substrate.

Further features of the present invention will become apparent from the following description of exemplary embodiments with reference to the attached drawings.

### BRIEF DESCRIPTION OF THE DRAWINGS

FIG. 1 is a configuration diagram of an image projection apparatus according to a first embodiment.

FIG. 2 is a configuration diagram of a light source apparatus according to the first embodiment.

FIGS. 3A and 3B are characteristic diagrams of a polarization separating element in the first embodiment.

FIG. 4 is a configuration diagram of a phosphor module according to the first embodiment.

FIG. 5 illustrates an image obtained by observing a surface of the phosphor module in the first embodiment using an AFM.

FIG. 6 explains a manufacturing method of the phosphor module according to the first embodiment.

FIG. 7 explains a manufacturing method of a phosphor module according to a modification of the first embodiment.

FIG. 8 explains a manufacturing method of a phosphor module according to a modification of a fourth embodiment.

FIG. 9 explains a manufacturing method of a phosphor module according to a fifth embodiment.

FIG. 10 explains a manufacturing method of a phosphor module according to a sixth embodiment.

FIG. 11 explains a manufacturing method of a phosphor module according to a seventh embodiment.

FIG. 12 explains a manufacturing method of a phosphor module according to an eighth embodiment.

FIG. 13 explains a manufacturing method of a phosphor module according to a ninth embodiment.

### DESCRIPTION OF THE EMBODIMENTS

Referring now to the accompanying drawings, a detailed description will be given of embodiments according to the present invention.

### First Embodiment

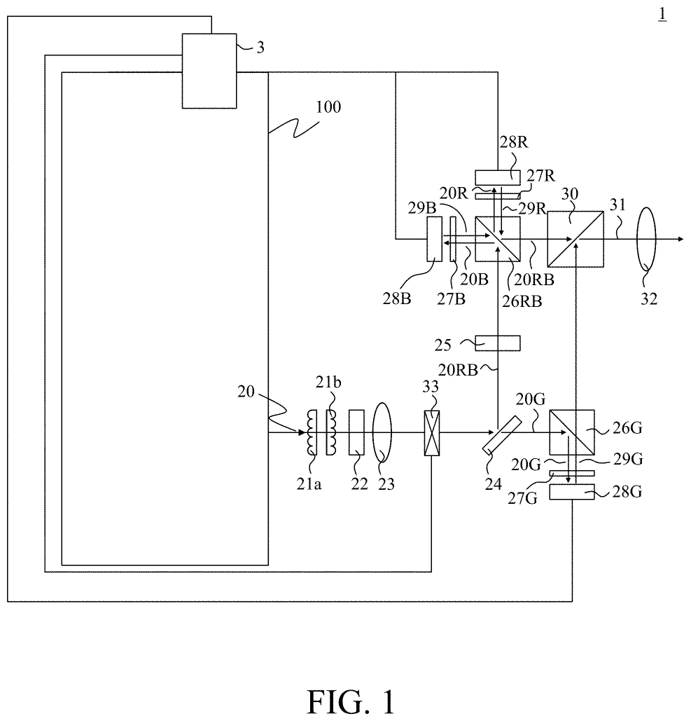

Referring now to FIG. 1, a description will be given of a configuration of an image projection apparatus (projector) 1 according to a first embodiment of the present invention. FIG. 1 is a configuration diagram of an image projection apparatus 1. In the following description, R, G, and B mean red, green, and blue, respectively.

Reference numeral 100 denotes a light source apparatus, reference numeral 20 denotes illumination light, reference numeral 21a denotes a first fly-eye lens, reference numeral 21b denotes a second fly-eye lens, reference numeral 22 denotes a polarization conversion element, reference numeral 23 denotes a fourth lens, reference numeral 24 denotes a dichroic mirror, and reference numeral 25 denotes a wavelength-selective phase plate. Reference numeral 26RB denotes a polarization beam splitter for RB (“RB polarization beam splitter”), reference numeral 26G denotes a polarization beam splitter for G (“G polarization beam splitter”), reference numeral 27R denotes a quarter waveplate for R (“R quarter waveplate”), reference numeral 27G denotes a quarter waveplate for G (“G quarter waveplate”), and 27B is a quarter waveplate for B (“B quarter waveplate”). Reference numeral 28R denotes a light modulation unit for R (“R light modulation unit”), reference numeral 28G denotes a light modulation unit for G (“G light modulation unit”), and reference numeral 28B denotes a light modulation unit for B (“B light modulation unit”). The R light modulation unit 28R, the G light modulation unit 28G, and the B light modulation unit 28B are light modulation elements that modulate the light from the light source apparatus 100 based on the image information and form the image light. Reference numeral 29 denotes modulated light, reference numeral 30 denotes a color combining prism, reference numeral 31 denotes projection light, and reference numeral 32 denotes a projection lens.

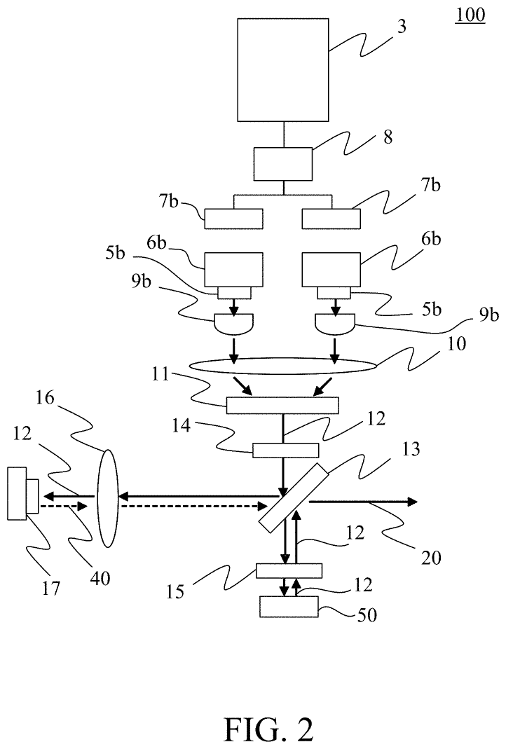

The illumination light 20 is divided into a plurality of light beams when transmitting through the first fly-eye lens 21a and the second fly-eye lens 21b, and enters the polarization conversion element 22. The polarization conversion element 22 converts the illumination light 20 as unpolarized light into linearly polarized light having a polarization direction aligned with one direction. Generally, a light beam from the laser diode (LD) is linearly polarized light, but the light beam from a phosphor module 17 (see FIG. 2) is unpolarized light having a disturbed polarization direction. Therefore, for an efficient polarization separation through the polarization beam splitter described later, the polarization direction is aligned with a predetermined direction using the polarization conversion element 22. In this embodiment, the polarization conversion element 22 converts the illumination light 20 into linearly polarized light (S-polarized light) having a polarization direction orthogonal to the paper plane of FIG. 1. The plurality of light beams as the illumination light 20 emitted from the polarization conversion element 22 are condensed by the fourth lens 23 and substantially uniformly superimposed on each light modulation unit (R light modulation unit 28R, G light modulation unit 28G, B light modulation 28B). Thereby, each light modulation unit is uniformly illuminated.

The illumination light 20 that has transmitted through the fourth lens 23 is guided by the dichroic mirror 24. The dichroic mirror 24 reflects the RB light 20RB and transmits the G light 20G in the illumination light 20. The S-polarized G light 20G that has transmitted through the dichroic mirror 24 enters the G polarization beam splitter 26G and then reflected by the polarization splitting plane and reaches the G light modulation section 28G. Here, the G light modulation unit 28G is a digitally driven reflection type liquid crystal display element. The R light modulation unit 28R and the B light modulation unit 28B each have the same structure as that of the G light modulation unit 28G. Each pixel of each light modulation unit is turned on and off within each frame period of the display image. Controlling the duty ratio of ON/OFF driving can provide a display of a desired gradation. A control unit 3 controls the R light modulation unit 28R, the G light modulation unit 28G, and the B light modulation unit 28B, respectively.

In the G light modulation unit 28G, the G light 20G is modulated based on the image information and reflected. Of the modulated light 29G, the S-polarized light component is reflected on the polarization splitting plane of the G polarization beam splitter 26G, is returned to the light source apparatus 100 side, and is removed from the projection light. On the other hand, the P-polarized light component of the modulated light 29G transmits through the polarization splitting plane of the G polarization beam splitter 26G. At this time, in a state where all polarized light components are converted into S-polarized light (in a state where black is displayed), the slow axis or the fast axis of the quarter waveplate 27G is adjusted to a direction approximately orthogonal to a plane including an incident optical axis upon the G polarization beam splitter 26G and a reflection optical axis from it. Thereby, the disturbance influence of the polarization state generated by the G polarization beam splitter 26G and the G light modulation unit 28G can be reduced. The modulated light 29G emitted from the G polarization beam splitter 26G reaches the color combining prism 30.

The RB light 20RB reflected by the dichroic mirror 24 enters the wavelength-selective phase plate 25. The wavelength-selective phase plate 25 rotates the polarization direction of the R light by 90 degrees and makes it P-polarized light, and transmits the B light as S-polarized light in the same polarization direction. The RB light 20RB that has transmitted through the wavelength-selective phase plate 25 enters the RB polarizing beam splitter 26RB. The RB polarization beam splitter 26RB transmits the R light 20R that is the P-polarized light and reflects the B light 20B that is the S-polarized light. The R light 20R that has transmitted through the polarization splitting plane in the RB polarization beam splitter 26RB is modulated based on the image information and reflected by the R light modulation unit 28R. Of the modulated light 29R, the P-polarized light component transmits through the polarization splitting plane in the RB polarizing beam splitter 26RB, is returned to the light source side, and is removed from the projection light. On the other hand, the S-polarized light component of the modulated light 29R is reflected on the polarization splitting plane in the RB polarization beam splitter 26RB and reaches the color combining prism 30.

The B light 20B reflected on the polarization splitting plane in the RB polarization beam splitter 26RB is modulated based on the image information and reflected by the B light modulation unit 28B. Of the modulated light 29B, the S-polarized light component is reflected on the polarization splitting plane in the RB polarization beam splitter 26RB, is returned to the light source side, and is removed from the projection light. On the other hand, the P-polarized light component of the modulated light 29B transmits through the polarization splitting plane in the RB polarization beam splitter 26RB and reaches the color combining prism 30. At this time, by adjusting the slow axes of the quarter waveplates 27R and 27B in the same manner similar to G, the black display of each of R and B can be adjusted.

The RB light 20RB thus combined into a single light beam and emitted from the RB polarizing beam splitter 26RB reaches the color combining prism 30. The color combining prism 30 transmits the R light and the B light and reflects the G light 20G. Projection light 31 combined by the color combining prism 30 is projected onto a projection surface such as a screen via a projection lens 32. Thereby, a color image as a projection image is displayed. The optical path illustrated in FIG. 1 shows the optical path of the image projection apparatus 1 displaying white. The following description assumes that the image projection apparatus 1 displays white unless otherwise specified.

Referring now to FIG. 2, a description will be given of the configuration of the light source apparatus 100 according to this embodiment. FIG. 2 is a configuration diagram of the light source apparatus 100. A blue light source (excitation light source) 5b is a semiconductor laser (blue LD) that emits blue light (excitation light), and is manufactured by using a GaN substrate. The blue light source 5b excites a phosphor module (wavelength conversion element) 17 described later. Although two blue light sources 5b are illustrated in FIG. 2, one blue light source 5b or three or more blue light sources 5b may be used. The blue light source 5b has a peak wavelength of 455 nm, and S-polarized light, which is linearly polarized light having a polarization direction orthogonal to the paper plane of FIG. 2, is emitted as excitation light 12.

The blue light source 5b is attached to a blue-light-source (“BLS”) heat sink 6b. The BLS heat sink 6b includes a copper plate or the like provided with heat radiating fins. The blue light source 5b and the BLS heat sink 6b may be in close contact with each other by a heat conductive member such as a heat conductive sheet. The BLS heat sink 6b is cooled by a BLS cooling unit 7b. The BLS cooling unit 7b is a fan. The rotation speed of the blue light source cooling unit 7b is controlled by a cooling control unit 8 based on the instruction of the control unit 3.

The blue light emitted from the blue light source 5b enters a blue collimator lens 9b. The blue collimator lens 9b makes substantially parallel (collimates) the light from the blue light source 5b. An arrow direction in FIG. 2 indicates a light traveling direction. A first lens 10 and a second lens 11 adjust a light beam diameter of the light emitted from the blue collimator lens 9b. The light emitted from the blue collimator lens 9b enters the first lens 10 and the second lens 11 and is emitted as excitation light 12. As described above, the excitation light 12 is the blue light as the S-polarized light and is applied to a retardation plate (phase difference plate) 14. The retardation plate 14 is a quarter waveplate. The excitation light 12 that has transmitted through the retardation plate 14 is converted from the S-polarized light to, for example, clockwise circularly polarized light, and is irradiated onto a polarization separating element 13.

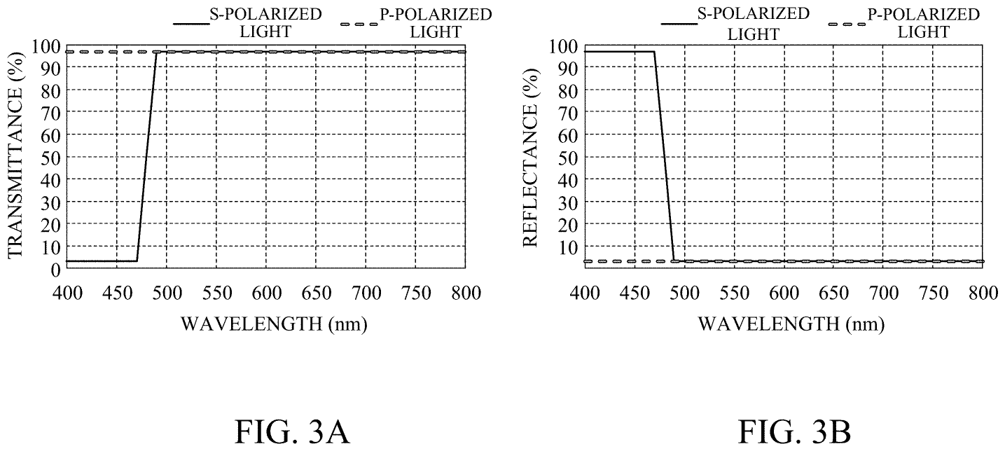

Referring now to FIGS. 3A and 3B, a description will be given of optical characteristics (transmittance characteristic, reflectance characteristic) of the polarization separating element 13. FIGS. 3A and 3B are characteristic diagrams (transmittance characteristic diagram, reflectance characteristic diagram) of the polarization separating element 13. In FIG. 3A, the ordinate axis represents transmittance (%) and the abscissa axis represents wavelength (nm). In FIG. 3B, the ordinate axis represents reflectance (%) and the abscissa axis represents wavelength (nm).

The polarization separating element 13 has a characteristic of reflecting the S-polarized light and of transmitting the P-polarized light for the blue light which is excitation light, and of transmitting both the S-polarized light and the P-polarized light for light having a longer wave than the blue light. Therefore, of the excitation light 12 incident on the polarization separating element 13, the S-polarized light component is reflected, and a third lens 16 condenses the excitation light 12 and forms a light irradiation area having a predetermined size on the phosphor module 17.

The phosphor module 17 is a wavelength conversion element that converts the excitation light 12 irradiated with the predetermined size into light having a predetermined wavelength as yellow fluorescent light 40 and emits the light. The fluorescent light 40 again enters the third lens 16, is condensed there, and enters the polarization separating element 13. As illustrated in FIG. 2, the fluorescent light 40 transmits through the polarization separating element 13 and becomes the illumination light 20.

On the other hand, of the excitation light 12 incident on the polarization separating element 13, the P-polarized light component transmits it, passes through the retardation plate 15, and is diffused and reflected by a diffusing reflective plate 50. The diffused and reflected excitation light 12 again passes through the retardation plate 15. By passing through the retardation plate 15 twice, the polarization state changes from the P-polarized light to the S-polarized light, and the light 12 is reflected by the polarization separating element 13 and becomes illumination light 20.

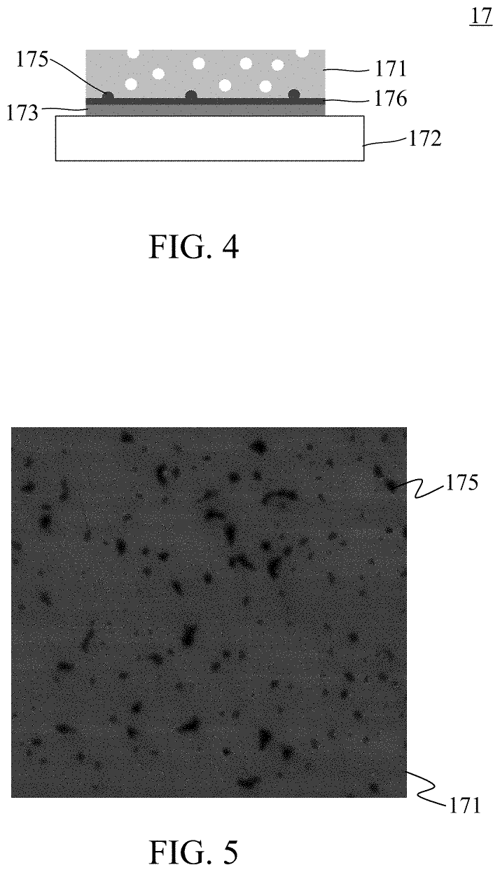

Referring now to FIG. 4, a description will be given of the configuration of the phosphor module 17 according to this embodiment. FIG. 4 is a block diagram of the phosphor module 17. The phosphor module 17 includes a phosphor plate 171, a module substrate 172, a reflective layer 173, and a flattening layer 176. The phosphor plate 171 is a wavelength conversion layer that converts light having a first wavelength (excitation light 12) into light having a second wavelength (fluorescent light 40). The reflective layer 173 reflects at least part of the light of the first wavelength or the light of the second wavelength. The flattening layer 176 is formed on at least one surface of the phosphor plate 171. The module substrate 172 is a substrate that holds the reflective layer 173.

The phosphor plate 171 is made of a material, such as a phosphor material (fluorescent particles, phosphor powder) such as YAG:Ce and LuAG. The phosphor plate 171 is a sintered body manufactured by sintering only fluorescent particles such as YAG:Ce and LuAG, or sintering it with other ceramic materials such as Al₂O₃ and SiO₂ and by processing them into a proper size. In this embodiment, the phosphor plate 171 has a size of 5 mm square with a thickness of 0.2 mm.

When the ceramic material is sintered, voids 175 are generated inside. This is because the powder increases the contact area at the initial stage of sintering and joins while coalescing during sintering of the ceramic material. Due to the particle size distribution and the agglutination of particles, not only an ideal neck growth but also a grain growth and a pore growth occur since small particles and pores coalesce. Thereafter, in the mid-term sintering and the final sintering, the pores disappear or coalesce, and some of the pores remain in the sintered ceramics, which become the voids 175. When the voids 175 expose on the surface of the phosphor plate 171, there are holes corresponding to the voids 175 on the surface of the phosphor plate 171.

FIG. 5 is an image obtained by observing the surface of the phosphor plate 171 with an AFM. The voids 175 can be confirmed from FIG. 5 on the phosphor plate 171 in addition to the part sintered with the phosphor material.

The module substrate 172 is made of a material having a high thermal conductivity such as aluminum, copper, an alloy of copper and tungsten, or an alloy of copper and molybdenum. The reflective layer 173 is provided on the flattening layer 176. The reflective layer 173 includes, for example, a layer in which a high-reflectance metal film such as aluminum or silver is evaporated, an enhanced reflection layer made of a dielectric multilayer film (dielectric film), or an enhanced reflective layer made of a dielectric multilayer film on a high-reflectance metal film. The reflective layer 173 may include a metal film, a protective film that protects the metal film, and a multilayer film including a dielectric film. The reflective layer 173 reflects the fluorescent light and the unconverted excitation light emitted from the phosphor plate 171 and can be used as the illumination light 20.

If the reflective layer 173 is evaporated directly on the phosphor plate 171, the reflective layer 173 is not deposited above the voids 175 exposed on the surface of the phosphor plate 171, so that a light amount usable for the illumination light 20 lowers. Therefore, in this embodiment, the flattening layer 176 is formed on the phosphor plate 171 in order to fill the voids 175 in the phosphor plate 171.

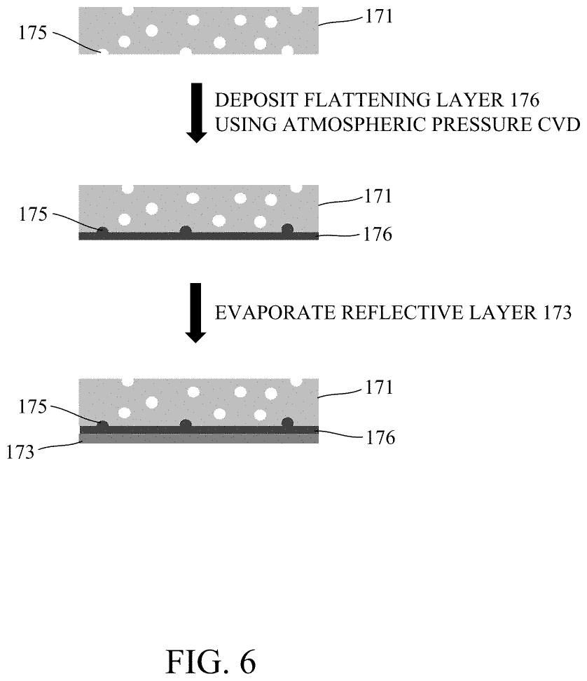

Referring now to FIG. 6, a description will be given of a manufacturing method of the phosphor module 17. FIG. 6 explains the manufacturing method of the phosphor module 17. First, the flattening layer 176 is formed on the phosphor plate 171. In this embodiment, the flattening layer 176 is formed by depositing TEOS (tetraethyl orthosilicate) on the phosphor plate 171 using the atmospheric pressure CVD (chemical vapor deposition). The CVD is a method for supplying a raw material gas containing a thin film component onto a substrate and for depositing a film by a chemical reaction on the surface of the substrate or in the gas phase. Since the growth rate is high, the film can be deposited with a thickness of 1 μm or more. This method can fill the voids 175 in the phosphor plate 171, and make the surface roughness Ra of the flattening layer 176 smaller than that of the phosphor plate 171.

Next, an optical layer (such as the reflective layer 173 and the antireflective film) is formed on the flattening layer 176. In this embodiment, the reflective layer 173 is evaporated as the optical layer on the flattening layer 176. The reflective layer 173 is, for example, a dielectric multilayer film optimized for the refractive indexes of the phosphor plate 171 and the flattening layer 176. The reflective layer 173 made of the dielectric multilayer film may be designed so that the reflectance of light in a wavelength range of at least one of the excitation light 12 and the fluorescent light 40 is 90% or higher for the refractive index of the phosphor plate 171. The refractive index of the phosphor plate 171 is about 1.8, which corresponds to the refractive index of the phosphor material. The refractive index of the flattening layer 176 is about 1.5, which is close to the refractive index of SiO₂. The reflective layer 173 may be optimized by regarding the flattening layer 176 as one of the dielectric multilayer films.

Next, the phosphor plate 171 on which the reflective layer 173 is evaporated is bonded to the module substrate 172. This embodiment uses for the bonding method liquid phase bonding that can maintain a high thermal conductivity. The liquid phase bonding is solder or the like. This embodiment disposes an alloy of gold and tin between the reflective layer 173 and the module substrate 172, performs a heat treatment, and joins the reflective layer 173 and the module substrate 172 together.

As a result, the heat generated when the excitation light 12 irradiated onto the phosphor plate 171 is converted into the fluorescent light 40 is transmitted to the module substrate 172 having a high thermal conductivity via the thin flattening layer 176, the thin reflective layer 173, and the liquid phase bonding layer made of an alloy of gold and tin. This structure can provide efficient cooling. The excitation light 12 irradiated onto the phosphor plate 171 and the fluorescent light 40 generated by the phosphor plate 171 are reflected by the reflective layer 173 formed on the flattening layer 176 on the phosphor plate 171, enters the third lens 16, and is used for the illumination light 20. This configuration can provide light utilization efficiency higher than that of direct forming of the direct reflection layer 173 on the phosphor plate 171 having the voids 175.

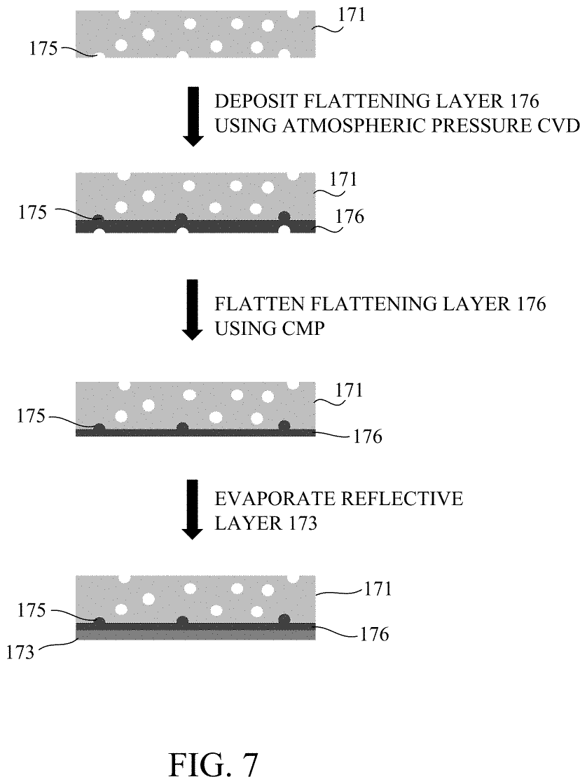

Referring now to FIG. 7, a description will be given of a manufacturing method of the phosphor module 17 according to a modification of this embodiment. FIG. 7 explains the manufacturing method of the phosphor module 17 according to the modification.

In this modification, the flattening layer 176 is evaporated on the phosphor plate 171 using an atmospheric pressure CVD, and then polished to improve the flatness. The polishing method includes, but is not limited to, mechanical polishing, chemical polishing, chemical mechanical polishing (CMP), colloidal silica polishing, and the like. Polishing after the flattening layer 176 is formed can further reduce the surface roughness Ra of the flattening layer 176. The surface roughness Ra of the flattening layer may be 100 nm or less, or 10 nm or less. For example, in this modification, the surface roughness Ra of the flattening layer 176 can be reduced down to 8 nm as a result of polishing after the flattening layer 176 is deposited by about 2 μm on the surface of the phosphor plate 171 having a surface roughness of 150 nm. In order to transfer the heat generated by the phosphor plate 171 to the module substrate 172 without a heat loss, the thickness of the polished flattening layer 176 may be 5 μm or less, or 1 μm or less.

This embodiment disposes the flattening layer 176 on the reflective layer 173 side of the phosphor plate 171 (between the phosphor plate 171 and the reflective layer 173), but the present invention is not limited to this embodiment. For example, the flattening layer 176 may be formed on the incident side of the excitation light 12 of the phosphor plate 171. In this case, an amount of the excitation light 12 reflected at the interface of the phosphor plate 171 can be reduced by forming an antireflective film against the excitation light 12 on the flattening layer 176 (by forming the flattening layer 176 between the phosphor plate 171 and the antireflective film). The antireflective film prevents the reflection of at least part of the light having the first wavelength or the light having the second wavelength.

The flattening layer 176 may be formed on the side surface of the phosphor plate 171. The method of depositing the flattening layer 176 is not limited to the atmospheric pressure CVD, and other methods may be used such as the reduced pressure CVD and the plasma CVD. The material of the flattening layer 176 is not limited to TEOS, and other materials may be deposited such as Poly-Si and Si₃N₄.

### Second Embodiment

A description will now be given of a manufacturing method of the phosphor module according to a second embodiment of the present invention. This embodiment relates to a method that forms the flattening layer 176 on the phosphor plate 171 and directly bonds it to the module substrate 172 or reflective layer 173 formed on the module substrate 172.

The method of forming the flattening layer 176 on the phosphor plate 171 is the same as that of the first embodiment. For example, polishing after the flattening layer 176 is formed can make the surface roughness Ra (≤100 nm) of the flattening layer 176 smaller than that of the phosphor plate 171.

The reflective layer 173 is evaporated on the module substrate 172 after the surface of the module substrate 172 is polished until its surface roughness becomes 100 nm or less by mechanical polishing, chemical polishing, CMP, colloidal silica polishing, or the like, similarly to the phosphor plate 171. Alternatively, after the reflective layer 173 is formed, the surface of the reflective layer 173 is polished by mechanical polishing, chemical polishing, CMP, colloidal silica polishing, or the like. These processes can reduce the surface roughness of the reflective layer 173a down to 100 nm or less.

When the surface roughness Ra of each joining surface of the flattening layer 176 and the reflective layer 173 formed on the phosphor plate 171 is 100 nm or less, or 10 nm or less, or 1 nm or less, these surfaces can be superimposed and directly bonded together. As a result, the heat generated when the excitation light 12 irradiated onto the phosphor plate 171 is converted into the fluorescent light 40 is transferred to the module substrate 172 having a high thermal conductivity through the thin reflective layer 173 and efficient cooling can be realized. The excitation light 12 irradiated onto the phosphor plate 171 and the fluorescent light 40 generated by the phosphor plate 171 are reflected by the reflection layer 173 formed on the module substrate 172, enter the third lens 16, and are used as the illumination light 20. This configuration can realize light utilization efficiency higher than that of direct forming the reflection layer 173 on the phosphor plate 171 having the voids 175.

A direct bonding method includes bonding methods such as a “diffusion bonding,” “room temperature bonding,” “anode bonding,” or “reaction bonding.” These direct bonding methods can maintain the strong bonding strength and the optical characteristics of the reflective layer 173 and reduce the thermal resistances of the phosphor plate 171 and the reflective layer 173.

In order to remove a natural oxide film and a contaminant layer existing on the bonding surface for activations, a first flat surface 171a of the phosphor plate 171 and a second flat surface 173a of the reflection layer 173 are respectively processed with an Ar beam or the like before bonding. The surface roughness Ra can be measured with an atomic force microscope (AFM), an optical surface shape measuring machine, or the like.

Thus, in each embodiment, the wavelength conversion element (phosphor module 17) includes the wavelength conversion layer (phosphor plate 171) and the flattening layer 176. The wavelength conversion layer converts the light having the first wavelength (excitation light 12) into the light having the second wavelength (fluorescent light 40). The flattening layer 176 is deposited on at least one surface (at least one of the lower, upper, or side surfaces) of the wavelength conversion layer. The surface roughness of the flattening layer 176 is smaller than that of the wavelength conversion layer.

### Third Embodiment

A description will be given of a third embodiment according to the present invention. This embodiment relates to a method of forming the flattening layer 176 by a liquid phase method (sol-gel method). The flattening layer 176 according to this embodiment is formed for the purpose of flattening the surface on the reflective layer 173 side while filling the recesses of the phosphor plate 171. As a characteristic of the flattening layer 176, the flattening layer 176 may be transparent at least in the wavelength range of the fluorescent light 40.

In this embodiment, the metal oxide constituting the flattening layer 176 is not particularly limited as long as it is a metal oxide, but it may be a metal oxide gel by the sol-gel method or metal oxide fine particles. Here, the metal oxide gel by the sol-gel method is formed by hydrolyzing a compound sol such as a metal alkoxide, introducing it to a polycondensation reaction, and heating it. Examples of the metal oxide include silica (SiO₂), titania (TiO₂), alumina (Al₂O₃), zinc oxide (ZnO), and zirconia (ZrO₂). The material of the flattening layer 176 in this embodiment uses silazane or silicate, but the material is not limited to this embodiment. In order to improve the thermal conductivity of the flattening layer 176, the metal fine particles, metal oxide fine particles, and the like may be contained.

In this embodiment, whether the metal oxide gel by the sol-gel method or the metal oxide fine particle is used, the flattening layer 176 is usually formed by a film using a wet film formation that coats a solvent solution on a phosphor and heats and sinters it. The coating method is not limited because it changes depending on the film thickness, its shape, and the like, but a spin coating method, a dip method, a screen printing method, and the like can be used. The temperature during manufacturing can be nearly room temperature, which is a normal working temperature but, if necessary, it may be heated up to a temperature below the boiling point of the solvent.

The thickness of the flattening layer 176 may be 10 μm or less, or 5 μm or less, or 1 μm or less from the viewpoint of the heat conduction. The thickness of the flattening layer 176 can be controlled by a coating amount of the solvent solution, the heating/sintering conditions, and the like.

The roughness on the surface of the flattening layer 176 may be 100 nm or less, or 10 nm or less, or 5 nm or less, using the surface roughness Ra as an index. When the surface roughness Ra is equal to or less than the above value, the characteristics of the reflective layer 173 can be fully acquired. When the surface roughness Ra cannot be sufficiently reduced only by the above steps, the flattening method described in the first embodiment may be used for the flattening layer 176. The surface roughness Ra can be measured by an atomic force microscope (AFM), an optical surface shape measuring machine, a stylus type step meter, or the like. The method of forming the reflective layer 173 and the module substrate 172 after the flattening layer 176 is formed is the same as that of the first embodiment.

The above steps can further flatten the surface of the formed flattening layer. As a result, the characteristics of the reflective layer 173 can be fully acquired, and the efficiency of the entire phosphor module can be improved.

### Fourth Embodiment

A description will now be given of a fourth embodiment according to the present invention. This embodiment relates to a method of forming the flattening layer 176 by the liquid phase method. The flattening layer 176 according to this embodiment is formed for the purpose of joining the module substrate 172 provided with the reflection layer 173 in advance and the phosphor plate 171 while filling the recesses in the phosphor plate 171. For the characteristics of the flattening layer 176, the flattening layer 176 may be transparent at least in the wavelength range of the excitation light 12 and the fluorescence light 40. A conceivable material of the flattening layer 176 may use the materials described in the third embodiment.

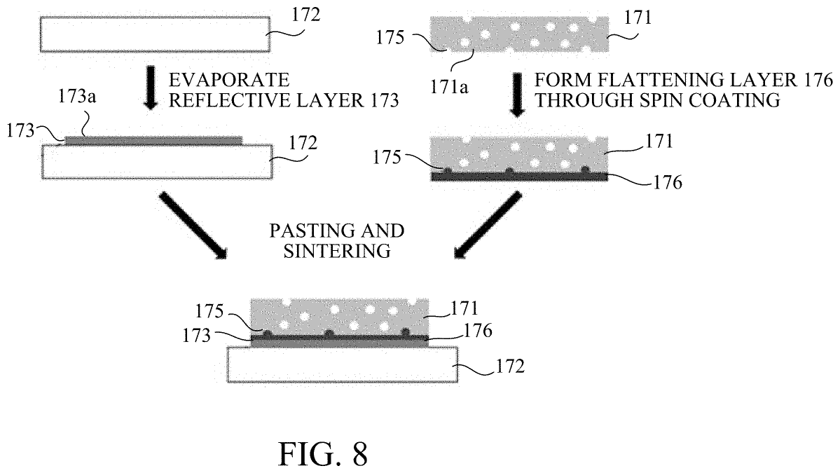

Referring now to FIG. 8, a description will be given of a manufacturing method of the phosphor module 17 according to a modification of this embodiment. FIG. 8 explains the manufacturing method of the phosphor module 17 according to the modification of this embodiment.

First, the reflective layer 173 is formed on the surface of the module substrate 172. The reflective layer 173 may have a high reflectance in the wavelength range of the fluorescent light 40 for the refractive index of the flattening layer 176. Next, a solvent solution as a raw material for the flattening layer 176 is coated onto the phosphor using a technique such as spin coating. Then, the reflective layer 173 formed on the module substrate 172 is pasted to the coated solvent solution. Then, the solvent solution is heated and sintered. Here, the materials of the reflective layer 173 and the module substrate 172 may use molten solvents having a sintering temperature lower than their heat resistant temperatures. The film thickness of the flattening layer and the surface roughness of the flattening layer may be in the ranges described in the third embodiment.

The above steps can collectively flatten the phosphor surface and pasting of the reflective layer. As a result, the cost of the phosphor module can be reduced.

### Fifth Embodiment

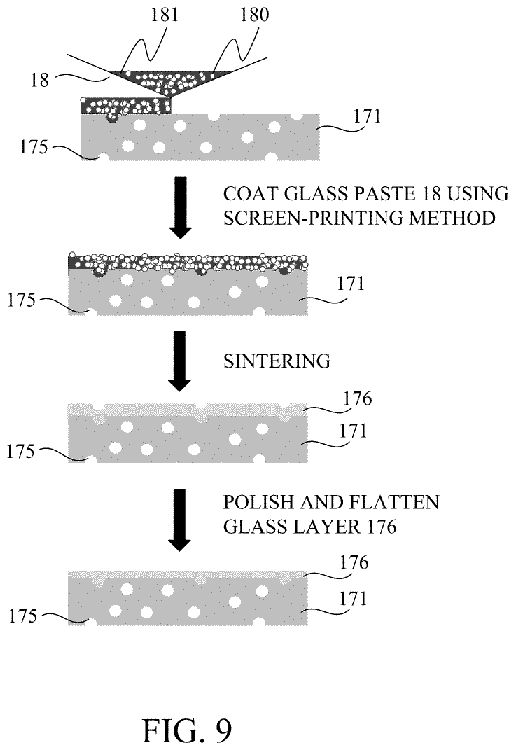

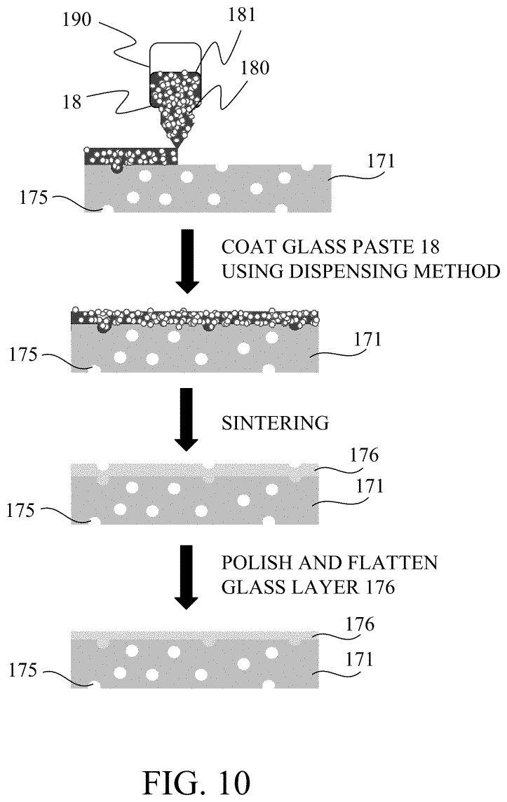

Referring now to FIG. 9, a description will now be given of a manufacturing method of the phosphor module 17 according to a fifth embodiment of the present invention. FIG. 9 explains the manufacturing method of the phosphor module 17 according to this embodiment. Since this embodiment makes the flattening layer 176 of a glass layer, a description will be given of a screen-printing method as a glass paste coating method.

As the glass paste 18, glass powder 180 and vehicle 181 smaller than the voids 175 generated in the phosphor plate 171 are used. Examples of the material of the glass powder 180 include soda lime glass, borosilicate glass, non-alkali glass, and quartz glass. Examples of the vehicle 181 include a binder such as a cellulosic resin such as an organic solvent and nitrocellulose, an acrylic resin, and polypropylene carbonate. In mixing the glass powder 180 and the vehicle 181, stirring may be made in order to suppress agglomerates of the glass powder 180 and the like. The glass paste 18 may be sufficiently vacuum defoamed before use.

The size of the void 175 is approximately the same as the particle size of each of the phosphor particles YAG:Ce, which is the main material of the phosphor plate 171, and other ceramic materials such as Al₂O₃ and SiO₂. Since the phosphor particles and the ceramic material have particle diameter variations according to the particle size distribution, the sizes of the voids 175 also have variations. This embodiment uses a material having a particle diameter of 1.0 μm at D50 for the phosphor particles and the ceramic material.

The particle diameter of the glass powder 180 is 0.1 μm, which is smaller than the size of the void 175. The particle diameter of the glass powder 180 may be equal to or less than one-third or one-tenth as large as the size of the void 175 or the particle diameter of the phosphor particles or the ceramic material. This is because the glass powder 180 enters and flattens the voids 175.

The glass paste 18 coated by the screen-printing method may be thicker than the void 175 in order for the glass powder 180 to enter the voids 175, and for that purpose, a mesh thickness of a screen mesh must be larger than the void 175. In order to set the thickness of the sintered glass layer 176 to 2 μm, this embodiment makes screen printing with the mesh thickness of 2.5 μm. This is because the glass layer 176 becomes thinner than the glass paste 18 when screen printing is made due to shrinking in the sintering step described below. In order to improve the adhesion between the glass layer 176 and the phosphor plate 171, the surface of the phosphor plate 171 may be subjected to the surface treatment such as UV ozone treatment or plasma treatment.

Then, after the glass paste 18 is screen-printed, it is sintered so that the glass layer 176 has a layer consisting of the glass material. Examples of the sintering method include thermal radiation heating by an electric furnace or the like, infrared heating, laser light irradiation, dielectric heating, and the like. In order to volatilize and remove the organic solvent in the glass paste 18, the drying step may be provided before the sintering treatment. If the organic solvent remains in the glass paste 18, components to be eliminated such as the binder resin may not be fully removed in the heating step.

After the drying step, the heat treatment is performed in the sintering temperature range of the glassy material in the glass paste 18. Sintering of the glassy material needs to be made at a temperature equal to or higher than the glass softening point (Ts). The sintering temperature range may be a temperature range from Ts to Ts+150° C. The heat treatment method is not particularly limited as long as the temperature of at least the glass paste 18 becomes the above temperature. The above procedure can form the glass layer 176 on the phosphor plate 171.

After the glass layer 176 is formed on the phosphor plate 171, polishing is made in order to further improve the flatness. Examples of the polishing method include mechanical polishing, chemical polishing, CMP, colloidal silica polishing, and the like. By polishing after the glass layer 176 is formed, the surface roughness Ra of the glass layer 176 becomes lower than the surface roughness Ra of the phosphor plate 171, and the surface roughness Ra can be 100 nm or less, or 10 nm or less.

### Sixth Embodiment

Referring now to FIG. 10, a description will be given of a manufacturing method of the phosphor module 17 according to a sixth embodiment of the present invention. FIG. 10 explains the manufacturing method of the phosphor module 17 according to this embodiment.

As the glass paste 18, glass powder 180 and vehicle 181 smaller than the voids 175 generated in the phosphor plate 171 are put into a dispenser 190. Then, the glass paste 18 is dispensed for the phosphor plate 171. A driving unit is attached to either the dispenser 190 or a stage holding the phosphor plate 171 so that the glass paste 18 can be dispensed for the phosphor plate 171 at different locations. The location to be dispensed may be only sites of the voids 175, or may cover the entire phosphor plate 171. Alternatively, the location to be dispensed may cover the entire phosphor plate 171 and a detector for detecting the voids 175 may be provided so as to adjust the dispense amount according to the positions and sizes of the voids 175, and to more effectively fill the glass paste 18 in the voids 175.

Making the thickness of the needle of the dispenser smaller than the voids 175 can more effectively inject the glass paste 18 into the voids 175. In that case, the particle diameter of the glass powder 180 used for the glass paste 18 may be smaller than the size of the needle. The size of the glass powder 180 may be ⅕ or less, or 1/10 or less of the size of the void 175. In order to improve the adhesion between the glass layer 176 and the phosphor plate 171, the surface of the phosphor plate 171 may be subjected to the surface treatment such as a UV ozone treatment or a plasma treatment.

Sintering follows dispensing so that the glass layer 176 has a layer consisting of the glass material. Examples of the sintering method include thermal radiation heating by an electric furnace or the like, infrared heating, laser light irradiation, dielectric heating, and the like. In order to volatilize and remove the organic solvent in the glass paste 18, the drying step may be provided before the sintering treatment. If the organic solvent remains in the glass paste 18, components to be eliminated such as the binder resin may not be fully removed in the heating step.

After the drying step, heat treatment is performed in the sintering temperature range of the glassy material in the glass paste 18. Sintering of the glassy material needs to be made at a temperature equal to or higher than the glass softening point (Ts). The sintering temperature range may be a temperature range from Ts to Ts+150° C. The heat treatment method is not particularly limited as long as the temperature of at least the glass paste 18 becomes the above temperature. The above procedure can form the glass layer 176 on the phosphor plate 171.

After the glass layer 176 is formed on the phosphor plate 171, polishing is made in order to further improve the flatness. Examples of the polishing method include mechanical polishing, chemical polishing, CMP, colloidal silica polishing, and the like. By polishing after the glass layer 176 is formed, the surface roughness Ra of the glass layer 176 becomes lower than the surface roughness of the phosphor plate 171, and the surface roughness Ra may be 100 nm or less, or 10 nm or less.

### Seventh Embodiment

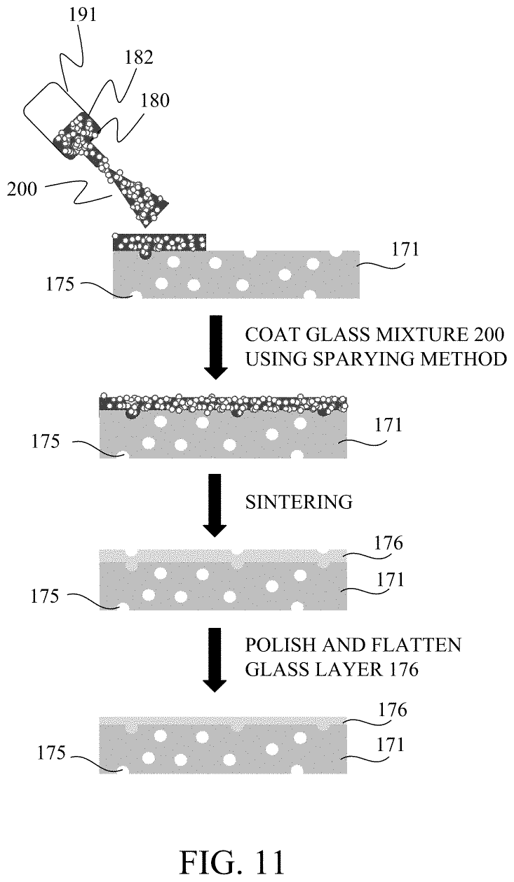

Referring now to FIG. 11, a description will be given of a manufacturing method of the phosphor module 17 according to a seventh embodiment of the present invention. FIG. 11 explains the method for manufacturing the phosphor module 17 according to this embodiment.

The glass powder 180 and organic solvent 182 are used as a glass mixed solution (mixture) 200, and the glass mixture 200 is formed on the surface of the phosphor plate 171 by spraying that sprays the glass powder 180 and the organic solvent 182 onto the phosphor plate 171 in the form of a mist with a spray gun 191. Ejecting in the form of mist can produce a homogeneous glass mixture 200 regardless of the shape and surface structure of the phosphor plate 171 and fill the glass powder 180 in the voids 175. In order to improve the adhesion between the glass layer 176 and the phosphor plate 171, the surface of the phosphor plate 171 may be subjected to the surface treatment such as a UV ozone treatment or a plasma treatment.

Sintering follows spraying so that the glass layer 176 has a layer consisting of the glass material. Examples of the sintering method include thermal radiation heating by an electric furnace or the like, infrared heating, laser light irradiation, dielectric heating, and the like. The heat treatment is performed in the sintering temperature range of the glassy material in the glass mixture 200. Sintering of the vitreous material needs to be performed at a temperature equal to or higher than the glass softening point (Ts). The sintering temperature range may be a temperature range from Ts to Ts+150° C. The heat treatment method is not particularly limited as long as the temperature of at least the glass paste 18 becomes the above temperature. The above procedure can form the glass layer 176 on the phosphor plate 171.

After the glass layer 176 is formed on the phosphor plate 171, polishing is made in order to further improve the flatness. Examples of the polishing method include mechanical polishing, chemical polishing, CMP, colloidal silica polishing, and the like. By polishing after the glass layer 176 is formed, the surface roughness Ra of the glass layer 176 becomes lower than that of the phosphor plate 171, and the surface roughness Ra can be 100 nm or less, or 10 nm or less.

### Eighth Embodiment

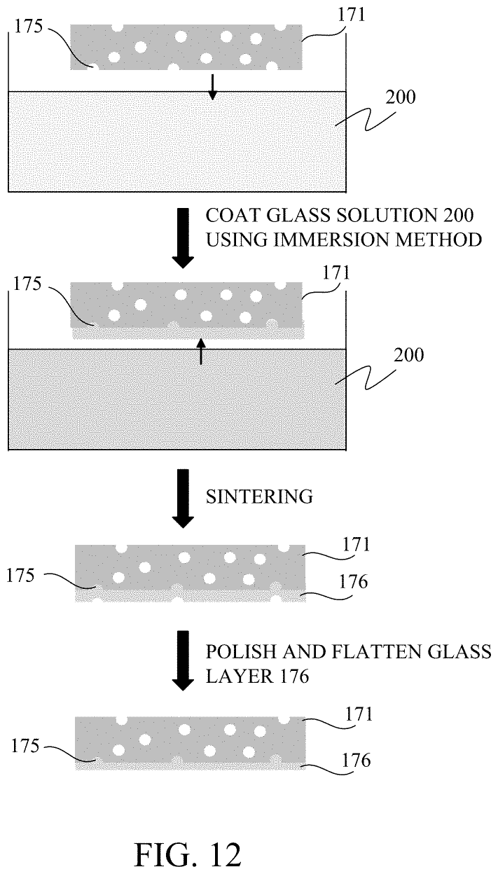

Referring now to FIG. 12, a description will be given of a manufacturing method of the phosphor module 17 according to an eighth embodiment of the present invention. FIG. 12 explains the method for manufacturing the phosphor module 17 according to this embodiment.

The phosphor plate 171 is immersed in a glass mixed solution (glass solution or mixture) 200 in which a glass material is dissolved, and gradually pulled up to naturally form a glass layer 176. The glass layer 176 can be formed by immersing the phosphor plate 171 in the gel solution of the glass material and heat-treating it.

After the glass layer 176 is formed on the phosphor plate 171, polishing is made in order to further improve the flatness. Examples of the polishing methods include mechanical polishing, chemical polishing, CMP, colloidal silica polishing, and the like. By polishing after the glass layer 176 is formed, the surface roughness Ra of the glass layer 176 becomes lower than that of the phosphor plate 171, and the surface roughness Ra can become 100 nm or less, or 10 nm or less.

### Ninth Embodiment

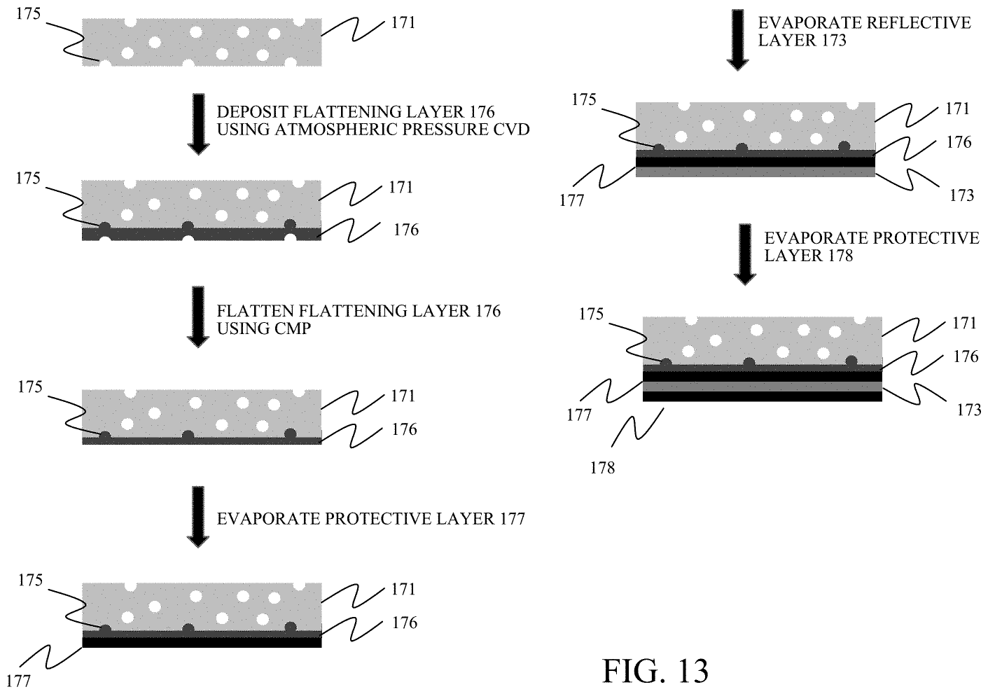

Referring now to FIG. 13, a description will now be given of a manufacturing method of the phosphor module 17 according to a ninth embodiment of the present invention. FIG. 13 explains the method for manufacturing the phosphor module 17 according to this embodiment.

First, a flattening layer 176 is formed on the phosphor plate 171. This embodiment forms the flattening layer 176 by depositing TEOS (tetraethyl orthosilicate) on the phosphor plate 171 by the atmospheric pressure CVD (chemical vapor deposition). The CVD is a method for supplying a raw material gas containing a thin film component onto a substrate and for depositing a film by a chemical reaction on the surface of the substrate or in the gas phase. Since the growth rate is high, the film can be deposited with a thickness of 1 μm or more. This method can fill the voids 175 in the phosphor plate 171, and make the surface roughness Ra of the flattening layer 176 smaller than that of the phosphor plate 171.

Next, an optical layer (such as the reflection layer 173 and the antireflective film) is formed on the flattening layer 176. The reflective layer 173 includes, for example, a layer in which a high-reflectance metal film such as aluminum or silver is evaporated, an enhanced reflection layer made of a dielectric multilayer film (dielectric film), or an enhanced reflection layer made of a dielectric multilayer film on a high-reflectance metal film. The reflective layer 173 may include a metal film, a protective film 177 that protects the metal film, and a multilayer film including a dielectric film. The reflective layer 173 reflects the fluorescent light and the unconverted excitation light emitted by the phosphor plate 171 and can be used as the illumination light 20.

This embodiment evaporates the reflective layer 173 as an optical layer on the flattening layer 176, and provides a protective film 177 that protects the metal film is provided between the flattening layer 176 and the reflective layer 173. The protective film is provided for the purpose of protecting the metal film from the oxidation and sulfurization. This is to protect the metal film from being deteriorated by direct or indirect contact of oxygen or other materials used in the flattening layer 176 with the metal film. When the reflective layer has a metal film and a dielectric multilayer film, the protective film 177 may be provided between the metal film and the dielectric multilayer film.

Although the phosphor plate 171 on which the reflective layer 173 is evaporated is adhered to the module substrate 172, this method may provide a protective film 178 between the reflective layer 173 and the module substrate 172. This is also to protect the metal film from deteriorating due to the direct or indirect contact with oxygen or other materials.

This embodiment uses as a bonding method liquid phase bonding that can provide a high thermal conductivity. The liquid phase bonding is solder or the like. This embodiment disposes an alloy of gold and tin between the reflective layer 173 and the module substrate 172, and performs the heat treatment to join the reflective layer 173 and the module substrate 172 together.

Each embodiment can provide a wavelength conversion element, a light source apparatus, an image projection apparatus, and a method for manufacturing a wavelength conversion element, each of which can improve the reliability and light utilization efficiency.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application Nos. 2020-146629, filed on Sep. 1, 2020, and 2021-040060, filed on Mar. 12, 2021, both of which are hereby incorporated by reference herein in their entirety.

What is claimed is:

1. A wavelength conversion element comprising:
a wavelength conversion layer configured to convert light having a first wavelength into light having a second wavelength; and
a flattening layer formed on at least one surface of the wavelength conversion layer,
wherein the flattening layer has a surface roughness smaller than that of the wavelength conversion layer, and
wherein the wavelength conversion layer is made of a sintered body obtained by sintering a phosphor material and a ceramic material.

2. The wavelength conversion element according to claim 1, further comprising a reflective layer configured to reflect at least part of the light having the first wavelength or the light having the second wavelength,
wherein the flattening layer is disposed between the wavelength conversion layer and the reflective layer.

3. The wavelength conversion element according to claim 2, wherein the reflective layer is made of a metal film.

4. The wavelength conversion element according to claim 2, wherein the reflective layer is made of a dielectric film.

5. The wavelength conversion element according to claim 2, wherein the reflective layer is a multilayer film including a metal film, a protective film configured to protect the metal film, and a dielectric film.

6. The wavelength conversion element according to claim 2, further comprising a substrate configured to hold the reflective layer.

7. The wavelength conversion element according to claim 1, further comprising an antireflective film configured to prevent at least part of the light having the first wavelength or the light having the second wavelength from being reflected,
wherein the flattening layer is disposed between the wavelength conversion layer and the antireflective film.

8. The wavelength conversion element according to claim 1, wherein the surface roughness of the flattening layer is 100 nm or less.

9. A light source apparatus comprising:
the wavelength conversion element according to claim 1; and
a light source configured to excite the wavelength conversion element.

10. An image projection apparatus comprising:
the light source apparatus according to claim 9; and
a light modulation element configured to modulate light from the light source apparatus to form image light based on image information.

11. A manufacturing method of a wavelength conversion element, the manufacturing method comprising the steps of:
forming a wavelength conversion layer configured to convert light having a first wavelength into light having a second wavelength; and
forming a flattening layer on at least one surface of the wavelength conversion layer,
wherein the wavelength conversion layer is made of a sintered body obtained by sintering a phosphor material and a ceramic material.

12. The manufacturing method according to claim 11, further comprising the step of polishing the flattening layer formed on the at least one surface of the wavelength conversion layer.

13. A manufacturing method of a wavelength conversion element, the manufacturing method comprising the steps of:
forming a wavelength conversion layer configured to convert light having a first wavelength into light having a second wavelength; and
bonding at least one surface of the wavelength conversion layer and a reflective layer held on a substrate with each other.
